(19) United States
(12) Patent Application Publication
(10) Pub. No.: US 2007/0273019 A1
(43) Pub. Date: Nov. 29, 2007

(54) Semiconductor package, chip carrier structure thereof, and method for fabricating the chip carrier

(75) Inventors: Chien Ping Huang, Hsinchu Hsein (TW); Ho-Yi Tsai, Taichung Hsien (TW)

Correspondence Address: EDWARDS ANGELL PALMER & DODGE LLP, P.O. BOX 55874, BOSTON, MA, 02205, US

(73) Assignee: Siliconware Precision Industries Co., Ltd., Taichung (TW)

(21) Appl. No.: 11/709,992

(22) Filed: Feb. 23, 2007

(30) Foreign Application Priority Data
Apr. 17, 2006 (TW) 095113597
May 29, 2006 (TW) 095118975

(51) Int. Cl. H01L 23/52; H01L 21/00

(52) U.S. Cl. 257/690; 257/738; 438/108; 438/113; 257/E23.141; 257/E21.001

(57) ABSTRACT

A semiconductor package, a chip carrier structure thereof, and a method for fabricating the chip carrier structure are provided. A substrate having a mounting region and a covering region is disposed in an opening of a carrier. A molding process is performed to form an encapsulant on the covering region of the substrate, with the mounting region of the substrate being exposed from the encapsulant. A cutting process is performed along edges of the substrate, such that the chip carrier structure is fabricated. A semiconductor chip is mounted on the mounting region of the substrate in a flip-chip manner, such that the semiconductor package is completed. The encapsulant formed on the covering region of the substrate provides the substrate with supporting strength and prevents poor electrical contact for the semiconductor package caused by substrate warpage.

### FIELD OF THE INVENTION

The present invention relates to semiconductor packages, chip carrier structures thereof, and methods for fabricating the chip carrier structures, and more particularly, to a flip-chip ball grid array (FCBGA) semiconductor package, a chip carrier structure thereof, and a fabrication method of the chip carrier structure.

### BACKGROUND OF THE INVENTION

Flip-chip ball grid array (FCBGA) semiconductor package is a well-known type of package characterized in comprising both an array of solder balls and a flip chip. The flip chip is incorporated in the package in a manner that an active surface of at least one chip is electrically connected to a surface of a substrate by a plurality of conductive bumps, and a gap between the chip and the substrate is filled with an underfill material that encapsulates the conductive bumps so as to enhance the strength of the conductive bumps and support the chip. The array of solder balls are implanted on another surface of the substrate and serve as input/output (I/O) connections for the package. The FCBGA package is advantageous as it greatly reduces the package size, making the chip and the substrate dimensionally similar, as well as it can reduce impedance and enhance electrical performance thereof without the use of conventional bonding wires, such that the FCBGA semiconductor package becomes widely used for packaging next-generation chips and electronic components. Related prior arts include U.S. Pat. Nos. 5,218,234, 6,225,704, 6,372,544, and 6,074,895.

The substrate of the FCBGA semiconductor package has a thickness of about 1.2 mm, with a core thereof having a thickness of about 0.8 mm, in order to prevent the occurrence of warpage in the substrate and the package. However, in view of the high electrical performance required for electronic products nowadays, a substrate with a thick core would undesirably lead to degradation of electrical performance. Thus, there has been proposed reducing the core of the substrate to a thickness of 0.4 mm or 0.2 mm or even using coreless substrates.

However, the substrate with a thin core for use in a FCBGA package is subject to warpage before a flip-chip bump mounting process, thereby adversely affecting the effective contact between the substrate and the conductive bumps on the chip. Further, after a reflow process for bonding the conductive bumps to the substrate, the substrate with a thin core may become warped and leads to cracks of the conductive bumps, thereby degrading the electrical contact and the product quality.

Referring to FIG. 1, U.S. Pat. No. 6,472,762 discloses a flip-chip semiconductor package, wherein a copper stiffener 14 is attached to a peripheral portion of a substrate 11 by means of an adhesive layer 13, so as to firmly hold the substrate 11 and prevent warpage of the substrate 11. As a result, a flip chip 12 can be securely mounted on the substrate 11, and warpage of the substrate and cracks of the conductive bumps after the reflow process can be reduced.

However, the method disclosed in U.S. Pat. No. 6,472,762 is cost ineffective, and also due to mismatch in thermal expansion coefficient (CTE) between the copper stiffener and the substrate, the adhesive layer is subject to delamination or conductive traces of the substrate are broken, thereby degrading the reliability of the fabrication processes. Moreover, the copper stiffener occupies surface area of the substrate and thus limits the space available for various active and passive components to be mounted on the substrate, such that the electrical functionality of the package cannot be effectively enhanced.

Therefore, the problem to be solved here is to develop a semiconductor package, a chip carrier structure thereof, and a method for fabricating the chip carrier structure, for providing a substrate with effective supporting strength, preventing warpage-induced poor electrical contact, avoiding the drawbacks of increase in cost, delamination and trace breaking caused by disposing a copper stiffener on the substrate, and providing more space on the substrate for mounting various active and passive components.

### SUMMARY OF THE INVENTION

In view of the aforesaid drawbacks of the prior art, a primary objective of the present invention is to provide a semiconductor package, a chip carrier structure thereof, and a method for fabricating the chip carrier structure, so as to provide a substrate with effective supporting strength and prevent warpage-induced poor electrical contact in the semiconductor package.

Another objective of the present invention is to provide a semiconductor package, a chip carrier structure thereof, and a method for fabricating the chip carrier structure, so as to eliminate the problems of increase in cost, delamination and trace breaking caused by disposing a stiffener on a substrate.

A further objective of the present invention is to provide a semiconductor package, a chip carrier structure thereof, and a method for fabricating the chip carrier structure, so as to increase space on a substrate for mounting various active and passive components and thereby enhance the electrical functionality of the semiconductor package.

In order to achieve the above and other objectives, the present invention discloses a method for fabricating a chip carrier structure, comprising the steps of: providing at least one substrate and a carrier having at least one opening, and disposing the substrate in the opening, the substrate having a mounting region and a covering region; and performing a molding process wherein the carrier with the substrate disposed therein is received in a mold and an encapsulant is formed on the covering region of the substrate, with the mounting region of the substrate being exposed from the encapsulant. Subsequently, a cutting process can be performed along edges of the substrate so as to separate the substrate from the carrier, and a semiconductor chip and/or a chip package can be mounted and electrically connected to the mounting region of the substrate, such that a semiconductor package is completed. The semiconductor chip is electrically connected to the mounting region of the substrate in a flip-chip manner by a plurality of conductive bumps, and the chip package is electrically connected to the mounting region of the substrate by a plurality of solder balls. Further, an underfill material can be applied on the mounting region of the substrate to encapsulate the conductive bumps and the semiconductor chip or encapsulate the solder balls and the chip package.

In another embodiment, the present invention discloses a method for fabricating a chip carrier structure, comprising the steps of: providing a substrate module plate comprising a plurality of substrates, wherein each of the substrates has a mounting region and a covering region surrounding the mounting region; and performing a molding process to form an encapsulant on the substrate module plate at positions corresponding to the covering regions of the substrates, wherein the encapsulant has a size larger than predetermined dimensions of each of the substrates and covers the covering region of each of the substrates, with the mounting region of each of the substrates being exposed from the encapsulant. Subsequently, a cutting process can be performed to cut the substrate module plate according to the predetermined dimensions of the substrates so as to separate the substrates from each other and form a plurality of chip carrier structures where electronic components, such as a semiconductor chip and/or a chip package, can then be mounted on the mounting regions of the substrates.

In the aforesaid fabrication methods, alternatively, after the molding process, the semiconductor chip and/or the chip package can be mounted on the mounting region of the substrate before the cutting process is performed on the substrate.

In an embodiment, the mold can be an insert mold having a protruding portion abutting against the mounting region of the substrate, so as to allow the encapsulant to be formed on the covering region of the substrate, with the mounting region of the substrate being exposed. In another embodiment, a tape can be attached to the mounting region of the substrate to cover the mounting region, such that the encapsulant is formed on the covering region of the substrate, and upon removal of the tape, the mounting region of the substrate is exposed. In a further embodiment, prior to the molding process, an electronic component, such as a semiconductor chip and/or a passive components, can be mounted and electrically connected to the covering region of the substrate, such that the electronic component is encapsulated by the encapsulant during the molding process, so as to enhance the electrical functionality of the semiconductor package by incorporation of the semiconductor chip and/or the passive component.

By the above fabrication method, the present invention also discloses a chip carrier structure and a semiconductor package with the chip carrier structure. The chip carrier comprises a substrate having a mounting region and a covering region; and an encapsulant covering the covering region of the substrate, with the mounting region of the substrate being exposed from the encapsulant. An electronic component, such as a semiconductor chip and/or a passive component, can be disposed on the covering region of the substrate and is encapsulated by the encapsulant. The semiconductor package comprises a substrate having a mounting region and a covering region; an encapsulant covering the covering region of the substrate, with the mounting region of the substrate being exposed from the encapsulant; and an electronic component, such as a semiconductor chip and/or a chip package, mounted and electrically connected to the mounting region of the substrate. The semiconductor chip is electrically connected to the substrate by a flip-chip technique, and an underfill material can be applied on the mounting region of the substrate.

Therefore, according to the semiconductor package, the chip carrier structure thereof, and the method for fabricating the chip carrier structure in the present invention, a substrate having a mounting region and a covering region and a carrier having an opening are provided, and the substrate is disposed in the opening of the carrier. An encapsulant is formed on the covering region of the substrate so as to provide the substrate with effective supporting strength and prevent warpage of the substrate. The mounting region of the substrate is exposed from the encapsulant, and allows a chip to be firmly mounted on the mounting region by conductive bumps, or allows a chip package to be mounted on the mounting region by solder balls. By such arrangement, the problems in the prior art such as increase in cost, delamination and trace breaking caused by disposing a stiffener on a substrate can be avoided.

Moreover, prior to a molding process for forming the encapsulant, a wire-bonded semiconductor chip and/or a passive component can be mounted on the covering region of the substrate, wherein the semiconductor chip is electrically connected to the substrate by bonding wires. As a result, during the molding process, the encapsulant formed on the covering region of the substrate also encapsulates the wire-bonded semiconductor chip and/or the passive component. This not only eliminates the problem of the stiffener occupying the space on the substrate for mounting a semiconductor chip and a passive component as in the prior art, but also enhances the overall electrical functionality of the semiconductor package.

### BRIEF DESCRIPTION OF THE DRAWINGS

The present invention can be more fully understood by reading the following detailed description of the preferred embodiments, with reference made to the accompanying drawings, wherein:

FIG. 1 (PRIOR ART) is a cross-sectional view of a flip-chip semiconductor package disclosed in U.S. Pat. No. 6,472,762;

FIGS. 2A to 2G are schematic diagrams showing a method for fabricating a semiconductor package and a chip carrier structure thereof according to a first embodiment of the present invention;

FIGS. 2B′ and 2C′ are cross-sectional views showing another example of mounting a substrate in an opening of a carrier for the fabrication method of the present invention;

FIGS. 3A to 3D are schematic diagrams showing a method for fabricating a semiconductor package and a chip carrier structure thereof according to a second embodiment of the present invention;

FIGS. 4A to 4C are cross-sectional views showing a method for fabricating a semiconductor package according to a third embodiment of the present invention;

FIG. 5 is a cross-sectional view showing a semiconductor package according to a fourth embodiment of the present invention;

FIGS. 6A and 6B are schematic diagrams showing a semiconductor package and a chip carrier structure thereof according to a fifth embodiment of the present invention;

FIG. 7 is a schematic diagram of a semiconductor package according to a sixth embodiment of the present invention;

FIGS. 8A to 8C are schematic diagrams showing a semiconductor package according to a seventh embodiment of the present invention; and

FIGS. 9A to 9D are schematic diagrams showing a method for fabricating a semiconductor package according to an eighth embodiment of the present invention.

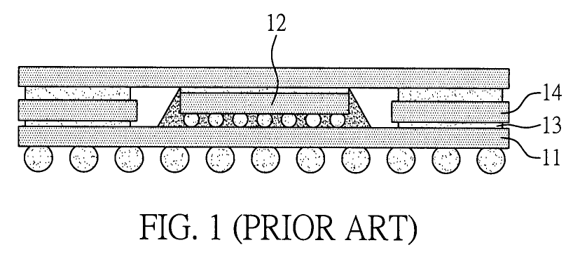

### DETAILED DESCRIPTION OF THE PREFERRED EMBODIMENTS

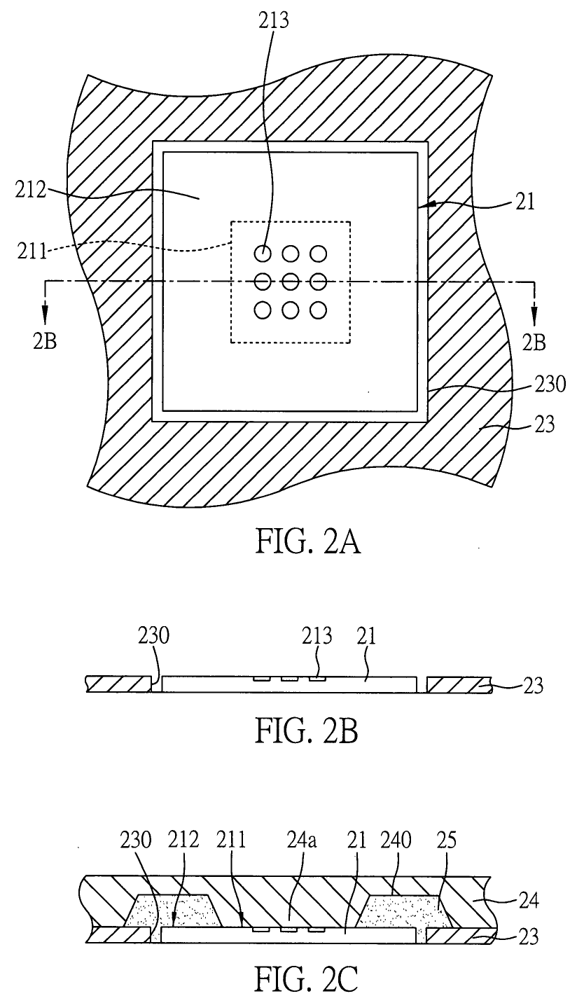

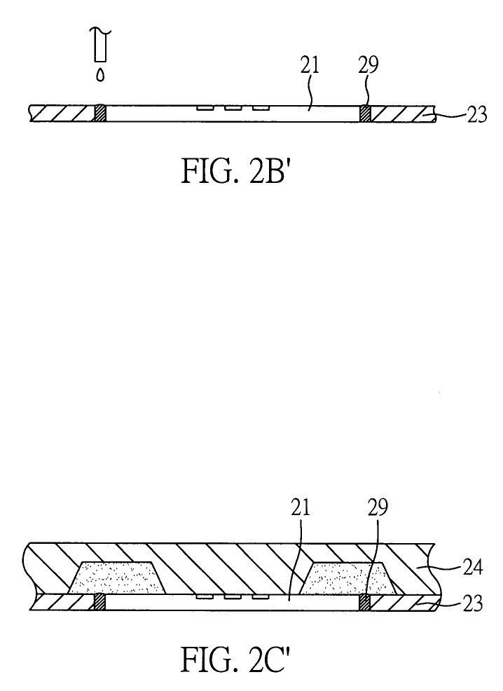

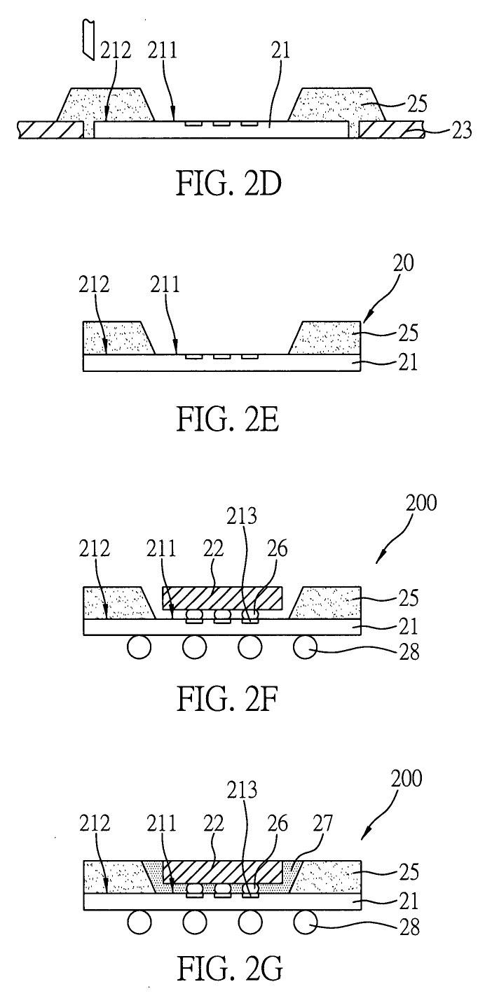

Preferred embodiments of a semiconductor package, a chip carrier structure thereof and a method for fabricating the semiconductor package and the chip carrier structure as proposed in the present invention are described as follows with reference to FIGS. 2 to 9. It should be understood that the drawings are simplified schematic diagrams only showing the elements relevant to the present invention, and the layout of elements could be more complicated in practical implementation.

### First Embodiment

FIGS. 2A to 2G are schematic diagrams showing a method for fabricating a semiconductor package and a chip carrier structure thereof according to a first embodiment of the present invention.

Referring to FIGS. 2A and 2B, wherein FIG. 2B is a cross-sectional view of FIG. 2A taken along line 2B-2B, at least one substrate 21 and a carrier 23 having at least one opening 230 are provided. The substrate 21 is disposed in the opening 230 of the carrier 23. The substrate 21 has a mounting region 211 (as defined by the dashed lines) and a covering region 212. The mounting region 211 is, for example, located at a central portion of the substrate 21, and the covering region 212 is located around the mounting region 211. An adhesive tape (not shown) can be attached to a bottom surface of the carrier 23 so as to seal one end of the opening 230, such that the substrate 21 can be mounted on the adhesive tape and received in the opening 230 of the carrier 23. The substrate 21 is a ball grid array substrate, for example, where a flip chip or a chip package can be mounted, and a plurality of bond pads 213 are formed in the mounting region 211 of the substrate 21. The fabrication method of the present invention can be performed on a single substrate or simultaneously performed on a plurality of substrates.

As shown in FIG. 2C, a molding process is carried out, wherein the carrier 23 with the substrate 21 disposed therein is received in a mold 24 having a cavity 240 therein, and the substrate 21 is received in the cavity 240. The mold 24 further comprises a protruding portion 24a protruded into the cavity 240 and abutting against the mounting region 211 of the substrate 21, such that an encapsulant 25 is formed on the covering region 212 of the substrate 21 by injecting an encapsulating resin into the cavity 240. The encapsulant 25 has a size larger than the size of the opening 230 of the carrier 23, making the encapsulant 25 fill a gap between the carrier 23 and the substrate 21, and the encapsulant 25 may have a height larger than, smaller than or equal to the height of an electronic component to be subsequently mounted on the mounting region 211 of the substrate 21.

As shown in FIGS. 2B′ and 2C′, alternatively, before the molding process, the gap between the carrier 23 and the substrate 21 can be filled with a filler material 29, such as a resin, so as to secure in position the substrate 21 in the opening 230 of the carrier 23. Then, the carrier 23 together with the substrate 21 are placed in the mold 24 to perform the molding process.

As shown in FIGS. 2D and 2E, the mold 24 is removed, and a cutting process is performed on the substrate 21 and the encapsulant 25 according to predetermined dimensions of the semiconductor package to be fabricated, such that a chip carrier structure 20 is formed. The chip carrier structure 20 comprises the substrate 21 with the mounting region 211 thereof being exposed from the encapsulant 25, and the encapsulant 25 formed on the covering region 212 surrounding the mounting region 211 of the substrate 21 so as to provide the substrate 21 with effective supporting strength and thereby prevent poor chip-mounting and electrical contact for the semiconductor package caused by substrate warpage.

As shown in FIG. 2F, a semiconductor chip 22 is mounted and electrically connected to the bond pads 213 in the mounting region 211 of the substrate 21 in a flip-chip manner by a plurality of conductive bumps 26, and a plurality of solder balls 28 are implanted on a surface of the substrate 21, which is not mounted with the semiconductor chip 22, and serve as input/output (I/O) connections, such that the semiconductor package 200 is fabricated. In this embodiment, the height of the encapsulant 25 can be equal to that of the semiconductor chip 22 mounted on the mounting region 211 of the substrate 21. Alternatively, a chip package (not shown) can be mounted and electrically connected to the bond pads in the mounting region 211 of the substrate 21 by solder balls.

As shown in FIG. 2G, an underfill material 27 can be applied on the mounting region 211 of the substrate 21 to encapsulate the conductive bumps 26 and fill a gap between the semiconductor chip 22 and the substrate 21 as well as support the semiconductor chip 22.

By the above fabrication method, the present invention provides a semiconductor package and a chip carrier structure thereof. As shown in FIG. 2F, the semiconductor package 200 comprises: the substrate 21 having the mounting region 211 and the covering region 212; the encapsulant 25 covering the covering region 212 of the substrate 21, with the mounting region 211 of the substrate 21 being exposed from the encapsulant 25; and the semiconductor chip 22 mounted and electrically connected to the mounting region 211 of the substrate 21 in a flip-chip manner. Further as shown in FIG. 2G, the underfill material 27 can be applied on the mounting region 211 of the substrate 21. As shown in FIG. 2E, the chip carrier structure 20 comprises: the substrate 21 having the mounting region 211 and the covering region 212; and the encapsulant 25 covering the covering region 212 of the substrate 21, with the mounting region 211 of the substrate 21 being exposed from the encapsulant 25.

### Second Embodiment

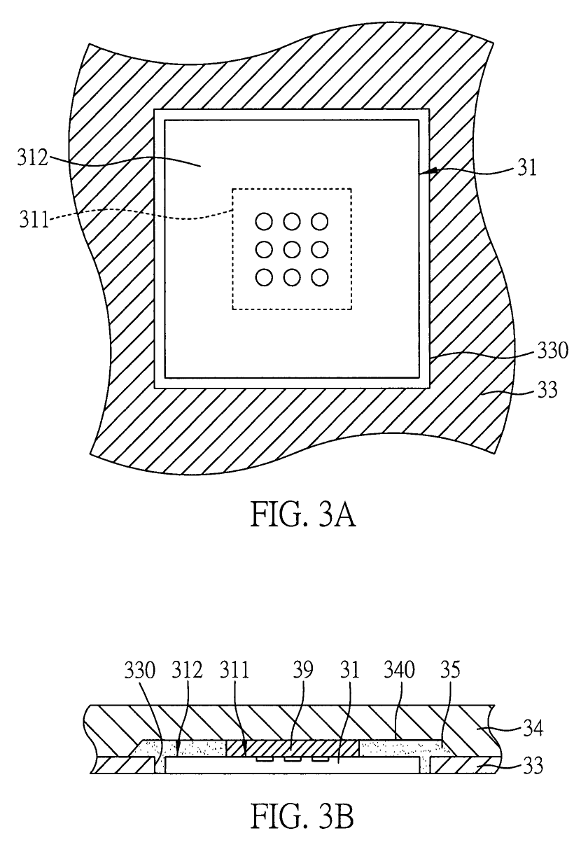

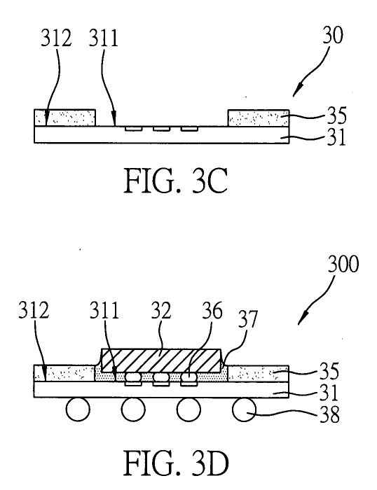

FIGS. 3A to 3D are schematic diagrams showing a method for fabricating a semiconductor package and a chip carrier structure thereof according to a second embodiment of the present invention.

As shown in FIG. 3A, at least one substrate 31 and a carrier 33 having at least one opening 330 are provided. The substrate 31 is disposed in the opening 330 of the carrier 33. The substrate 31 has a mounting region 311 (as defined by the dashed lines) and a covering region 312.

As shown in FIG. 3B, a tape 39 is attached to the mounting region 311 of the substrate 31 and covers the mounting region 311. Then, a molding process is performed, wherein the carrier 33 with the substrate 31 disposed therein is received in a mold 34, allowing the tape 39 to abut again a top wall of a cavity 340 of the mold 34, such that an encapsulant 35 is formed on the covering region 312 of the substrate 31 by injecting an encapsulating resin into the cavity 340 of the mold 34. The tape 39 further prevents the encapsulating resin from flashing to the mounting region 311 of the substrate 31, and also makes the fabrication cost of the mold 34 reduced. In this embodiment, the height of the encapsulant 35 can be smaller than that of a semiconductor chip to be subsequently mounted on the mounting region 311 of the substrate 31.

As shown in FIG. 3C, the mold 34 and the tape 39 are removed such that the mounting region 311 of the substrate 31 is exposed from the encapsulant 35. Then, a cutting process is performed on the substrate 31 and the encapsulant 35 according to predetermined dimensions of the semiconductor package to be fabricated, such that a chip carrier structure 30 is completed.

As shown in FIG. 3D, a semiconductor chip 32 is mounted and electrically connected to the mounting region 311 of the substrate 31 in a flip-chip manner by a plurality of conductive bumps 36. An underfill material 37 can be applied on the mounting region 311 of the substrate 31 to encapsulate the conductive bumps 36 and fill a gat between the semiconductor chip 32 and the substrate 31 as well as support the semiconductor chip 32. A plurality of solder balls 38 are implanted on a surface of the substrate 31, which is not mounted with the semiconductor chip 32, and serve as I/O connections, such that the semiconductor package 300 is fabricated.

### Third Embodiment

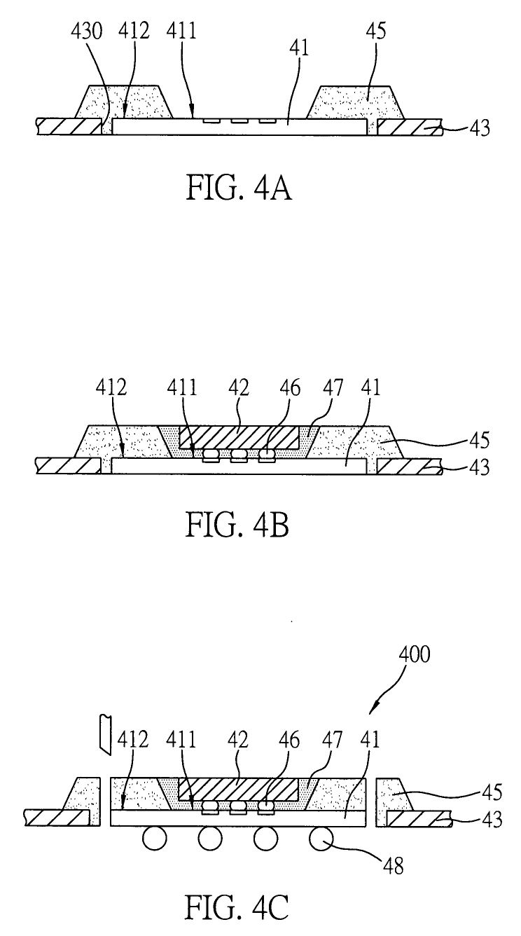

FIGS. 4A to 4C are cross-sectional views showing a method for fabricating a semiconductor package and a chip carrier structure thereof according to a third embodiment of the present invention.

As shown in FIG. 4A, similarly to the methods described in the above embodiments, a substrate 41 is disposed in an opening 430 of a carrier 43, and then a molding process is performed to form an encapsulant 45 on a covering region 412 of the substrate 41, leaving a mounting region 411 of the substrate 41 exposed from the encapsulant 45.

As shown in FIG. 4B, a semiconductor chip 42 is mounted and electrically connected to the mounting region 411 of the substrate 41 in a flip-chip manner by a plurality of conductive bumps 46. An underfill material 47 is applied on the mounting region 411 of the substrate 41 to encapsulate the conductive bumps 46 and support the semiconductor chip 42.

As shown in FIG. 4C, a cutting process is performed on the substrate 41 and the encapsulant 45 according to predetermined dimensions of the semiconductor package to be fabricated. A plurality of solder balls 48 are implanted on a surface of the substrate 41, which is not mounted with the semiconductor chip 42, and serve as I/O connections, such that the semiconductor package 400 is fabricated.

### Fourth Embodiment

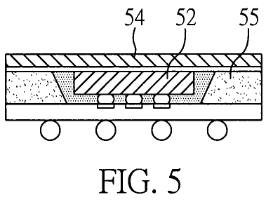

FIG. 5 is a cross-sectional view of a semiconductor package according to a fourth embodiment of the present invention.

The semiconductor package of this embodiment primarily differs from those of the above embodiments in that, as shown in FIG. 5, an electronic component, such as a semiconductor chip 52, is mounted on a mounting region of a substrate, and a heat sink 54 is provided on the semiconductor chip 52 and an encapsulant 55 formed on the substrate so as to enhance the overall heat dissipating performance of the semiconductor package.

### Fifth Embodiment

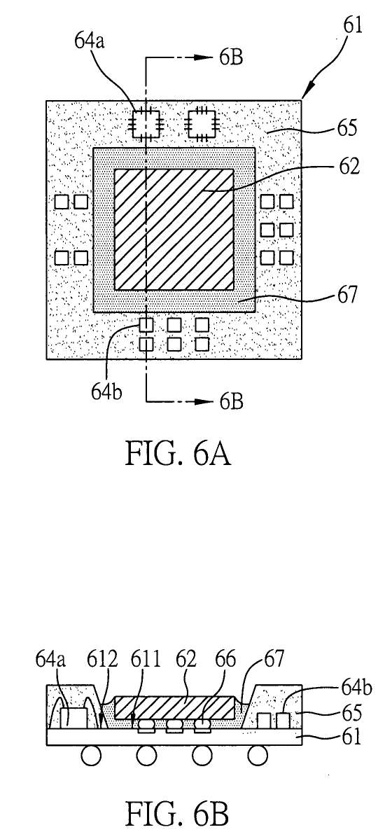

FIGS. 6A and 6B are respectively a top view and a cross-sectional view of a semiconductor package and a chip carrier structure thereof according to a fifth embodiment of the present invention.

The semiconductor package of this embodiment primarily differs from those of the above embodiments in that, as shown in FIGS. 6A and 6B, prior to a molding process, at least one electronic component, such as a semiconductor chip 64a and/or a passive component 64b, are mounted and electrically connected to a covering region 612 of a substrate 61, wherein the semiconductor chip 64a is electrically connected to the substrate 61 by bonding wires, such that an encapsulant 65 formed on the covering region 612 of the substrate 61 encapsulates the semiconductor chip 64a and the passive components 64b, with a mounting region 611 of the substrate 61 being exposed from the encapsulant 65. This thereby enhances the electrical functionality of the semiconductor package by means of various electronic components disposed on the substrate.

Subsequently, a semiconductor chip 62 can be mounted on the mounting region 611 of the substrate 61 in a flip-chip manner by a plurality of conductive bumps 66, and then an underfill material 67 can be applied on the mounting region 611 of the substrate 61 to encapsulate the conductive bumps 66.

In this embodiment, the height of the encapsulant 65 is larger than that of the semiconductor chip 62 mounted on the mounting region 611 of the substrate 61.

### Sixth Embodiment

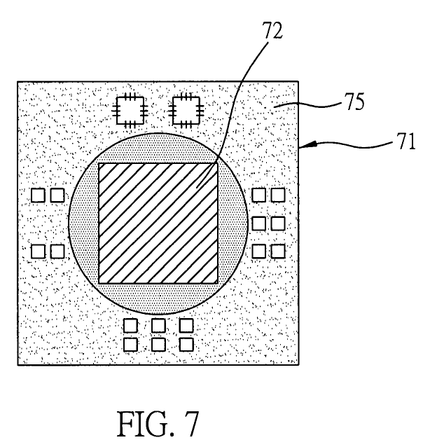

FIG. 7 is a top view of a semiconductor package according to a sixth embodiment of the present invention.

The semiconductor package of this embodiment primarily differs from those of the above embodiments in that, as shown in FIG. 7, an encapsulant 75 formed on a substrate 71 defines a receiving space on the substrate 71 for receiving an electronic component such as a flip-chip semiconductor chip 72 therein, and the receiving space is not limited to a square shape but can be flexibly shaped as polygon or circular, etc. according to practical requirement.

### Seventh Embodiment

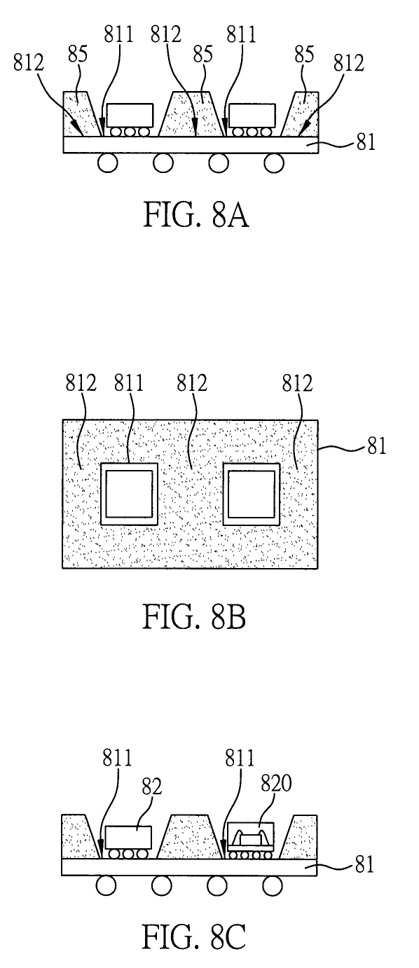

FIGS. 8A and 8B are respectively a cross-sectional view and a top view of a semiconductor package according to a seventh embodiment of the present invention.

The semiconductor package of this embodiment primarily differs from those of the above embodiments in that, as shown in FIGS. 8A and 8B, a plurality of mounting regions 811 can be formed on a substrate 81 in response to the number of semiconductor chips to be carried thereon. A covering region 812 is formed around each of the mounting regions 811 of the substrate 81 respectively, and an encapsulant 85 is formed on the covering region 812 so as to provide the substrate 81 with effective supporting strength and thereby prevent poor chip-mounting and electrical contact for the semiconductor package caused by substrate warpage.

Referring to FIG. 8C, in addition to a semiconductor chip 82, a chip package 820 may also be mounted on the mounting regions 811 of the substrate 81 and is electrically connected to the substrate 81 by solder balls.

### Eighth Embodiment

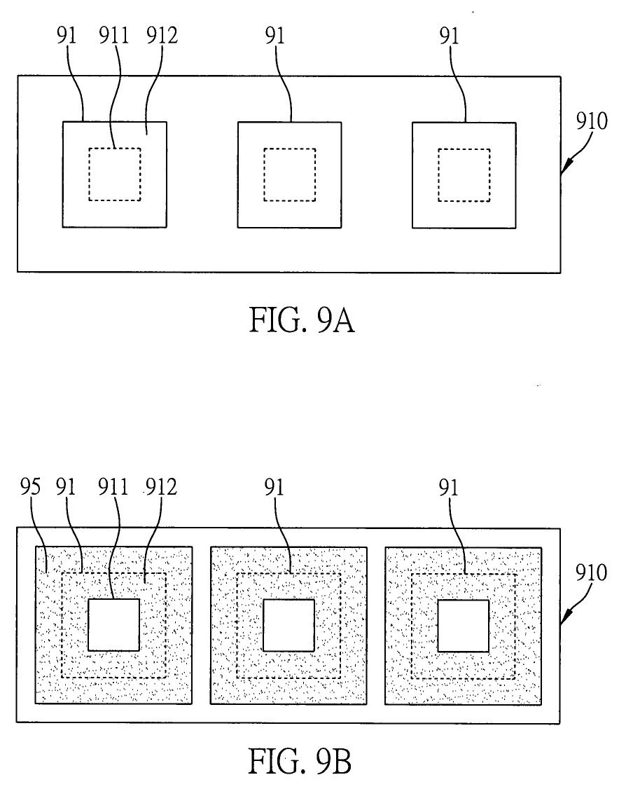

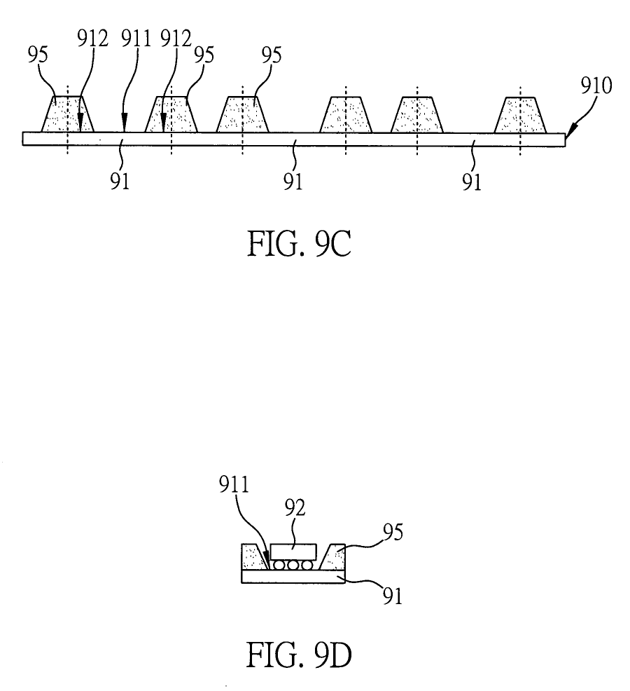

FIGS. 9A to 9D are schematic diagrams showing a method for fabricating a semiconductor package according to an eighth embodiment of the present invention.

As shown in FIG. 9A, a strip-shaped or sheet-shaped substrate module plate 910 comprising a plurality of substrates 91 is provided (this embodiment illustrates a strip-shaped substrate module plate). Each of the substrates 91 has a mounting region 911 and a covering region 912 surrounding the mounting region 911.

As shown in FIGS. 9B and 9C, wherein FIG. 9C is a cross-sectional view of FIG. 9B, a molding process is carried out to form an encapsulant 95 on the substrate module plate 910 at positions corresponding to the substrates 91, wherein the encapsulant 95 has a size larger than predetermined dimensions of each of the substrates 91 (as indicated by the dashed lines in FIG. 9B) and covers the covering regions 912 of the substrates 91, with the mounting regions 911 of the substrates 91 being exposed from the encapsulant 95.

To form the encapsulant 95, any one of the molding processes described in the above embodiments can be performed. For example, the substrate module plate can be received in a mold (not shown) having protruding portions abutting against the mounting regions of the substrates so as to allow the encapsulant to be formed on the covering regions of the substrates. Alternatively, a tape (not shown) can be disposed on the mounting regions of the substrates to cover the mounting regions, and then the substrate module plate is received in the mold with the tape abutting against a top wall of a cavity of the mold, such that the encapsulant is formed on the covering regions of the substrates.

Moreover, as described in the above fifth embodiment, prior to the molding process, at least one electronic component (not shown), such as a semiconductor chip and/or a passive component, can be mounted and electrically connected to the covering regions of the substrates, and then the encapsulant is formed on the covering regions of the substrates and encapsulates the electronic component, with the mounting regions of the substrates being exposed from the encapsulant.

As shown in FIG. 9D, a cutting process is performed on the substrate module plate 910 and the encapsulant 95 according to the predetermined dimensions of the substrates 91, such that a plurality of chip carrier structures are formed where an electronic components, such as a semiconductor chip 92 or a chip package, can be subsequently mounted on the mounting region 911 of each of the substrates 91. Alternatively, the semiconductor chip 92 or the chip package can be mounted on the substrate module plate 910 at a position corresponding to each of the substrate 91, and then the substrate module plate 910 is cut along edges of the substrates 91 corresponding to the predetermined dimensions of the substrates 91 so as to form a plurality of semiconductor packages.

Moreover, an underfill material (not shown) can be applied on the mounting region of each of the substrates to encapsulate a conductive material for electrically connecting the semiconductor chip or the chip package to the substrate, as well as to support the semiconductor chip or the chip package.

Therefore, according to the semiconductor package, the chip carrier structure thereof, and the method for fabricating the chip carrier structure in the present invention, a substrate having a mounting region and a covering region and a carrier having an opening are provided, and the substrate is disposed in the opening of the carrier. An encapsulant is formed on the covering region of the substrate so as to provide the substrate with effective supporting strength and prevent warpage of the substrate. The mounting region of the substrate is exposed from the encapsulant, and allows a chip to be firmly mounted on the mounting region by conductive bumps, or allows a chip package to be mounted on the mounting region by solder balls. By such arrangement, the problems in the prior art such as increase in cost, delamination and trace breaking caused by disposing a stiffener on a substrate can be avoided.

Moreover, prior to a molding process for forming the encapsulant, a wire-bonded semiconductor chip and/or a passive component can be mounted on the covering region of the substrate, wherein the semiconductor chip is electrically connected to the substrate by bonding wires. As a result, during the molding process, the encapsulant formed on the covering region of the substrate also encapsulates the wire-bonded semiconductor chip and/or the passive component. This not only eliminates the problem of the stiffener occupying the space on the substrate for mounting a semiconductor chip and a passive component as in the prior art, but also enhances the overall electrical functionality of the semiconductor package.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A method for fabricating a chip carrier structure, comprising the steps of:
providing at least one substrate and a carrier having at least one opening, and disposing the substrate in the opening of the carrier, the substrate having a mounting region and a covering region; and
performing a molding process wherein the carrier with the substrate disposed therein is received in a mold, and an encapsulant is formed on the covering region of the substrate, with the mounting region of the substrate being exposed from the encapsulant.

2. The method of claim 1, further comprising performing a cutting process along edges of the substrate so as to separate the substrate from the carrier.

3. The method of claim 2, further comprising before or after the cutting process, mounting and electrically connecting a semiconductor chip and/or a chip package to the mounting region of the substrate, wherein the semiconductor chip is electrically connected to the mounting region of the substrate in a flip-chip manner by a plurality of conductive bumps, and the conductive bumps are encapsulated by an underfill material.

4. The method of claim 1, wherein during the molding process where the carrier is received in the mold, the mold comprises a protruding portion abutting against the mounting region of the substrate so as to allow the encapsulant to be formed on the covering region of the substrate.

5. The method of claim 1, wherein a tape is disposed on and covers the mounting region of the substrate and abuts against a top wall of a cavity of the mold so as to allow the encapsulant to be formed on the covering region of the substrate during the molding process.

6. The method of claim 1, further comprising, before the molding process, mounting and electrically connecting an electronic component to the covering region of the substrate, such that the encapsulant formed on the covering region of the substrate encapsulates the electronic component, with the mounting region of the substrate being exposed from the encapsulant.

7. The method of claim 6, wherein the electronic component is one of a semiconductor chip and a passive component, the semiconductor chip being electrically connected to the substrate by bonding wires.

8. The method of claim 1, wherein the encapsulant fills a gap between the carrier and the substrate.

9. The method of claim 1, further comprising, before the molding process, filling a gap between the carrier and the substrate with a resin material so as to secure in position the substrate in the opening of the carrier.

10. A method for fabricating a chip carrier structure, comprising the steps of:
providing a substrate module plate comprising a plurality of substrates, each of the substrates having a mounting region and a covering region surrounding the mounting region; and
performing a molding process to form an encapsulant on the substrate module plate at positions corresponding to the substrates, wherein the encapsulant has a size larger than predetermined dimensions of each of the substrates and covers the covering region of each of the substrates, with the mounting region of each of the substrates being exposed from the encapsulant.

11. The method of claim 10, further comprising performing a cutting process to cut the substrate module plate according to the predetermined dimensions of the substrates so as to separate the substrates from each other.

12. The method of claim 11, further comprising before or after the cutting process, mounting a semiconductor chip and/or a chip package on the mounting regions of the substrates.

13. The method of claim 10, wherein during the molding process, the mold comprises protruding portions abutting against the mounting regions of the substrates so as to allow the encapsulant to be formed on the covering regions of the substrates.

14. The method of claim 10, wherein a tape is disposed on and covers the mounting region of each of the substrates and abuts against a top wall of a cavity of the mold so as to allow the encapsulant to be formed on the covering regions of the substrates during the molding process.

15. The method of claim 10, further comprising, before the molding process, mounting and electrically connecting an electronic component to the covering region of each of the substrates, such that the encapsulant formed on the covering regions of the substrates encapsulates the electronic components, with the mounting regions of the substrates being exposed from the encapsulant.

16. A chip carrier structure comprising:
a substrate having a mounting region and a covering region; and
an encapsulant covering the covering region of the substrate, with the mounting region of the substrate being exposed from the encapsulant.

17. The chip carrier structure of claim 16, further comprising an electronic component mounted and electrically connected to the covering region of the substrate and encapsulated by the encapsulant formed on the covering region of the substrate.

18. The chip carrier structure of claim 17, wherein the electronic component is one of a semiconductor chip and a passive component, the semiconductor chip being electrically connected to the substrate by bonding wires.

19. The chip carrier structure of claim 16, wherein the mounting region of the substrate is for mounting and electrically connecting an electronic component thereto.

20. The chip carrier structure of claim 19, wherein the electronic component is one of a semiconductor chip and a chip package, the semiconductor chip being mounted and electrically connected to the mounting region of the substrate by a plurality of conductive bumps that are encapsulated by an underfill material.

21. A semiconductor package comprising:
a substrate having at least one mounting region and a covering region;
an encapsulant covering the covering region of the substrate, with the at least on mounting region of the substrate being exposed from the encapsulant; and
at least one electronic component mounted and electrically connected to the at least one mounting region of the substrate.

22. The semiconductor package of claim 21, wherein the electronic component is one of a semiconductor chip and a chip package.

23. The semiconductor package of claim 22, wherein the semiconductor chip is mounted and electrically connected to the mounting region of the substrate by a plurality of conductive bumps, and the conductive bumps are encapsulated by an underfill material.

24. The semiconductor package of claim 21, further comprising a heat sink disposed on the electronic component and the encapsulant.

25. The semiconductor package of claim 21, further comprising another electronic component mounted and electrically connected to the covering region of the substrate and encapsulated by the encapsulant formed on the covering region of the substrate.

26. The semiconductor package of claim 25, wherein the electronic component mounted to the covering region of the substrate is one of a semiconductor chip and a passive component, the semiconductor chip being electrically connected to the substrate by bonding wires.

27. The semiconductor package of claim 21, wherein the encapsulant formed on the covering region of the substrate defines a receiving space on the substrate for receiving the electronic component therein, and the receiving space has a shape of one of square, circle, and polygon.

28. The semiconductor package of claim 21, wherein the encapsulant has a height larger than, less than or equal to a height of the electronic component mounted on the mounting region of the substrate.
